(19) United States
(12) Patent Application Publication
(10) Pub. No.: US 2014/0252550 A1
(43) Pub. Date: Sep. 11, 2014

(54) STACK CAPACITOR STRUCTURE AND MANUFACTURING METHOD THEREOF

(71) Applicant: INOTERA MEMORIES, INC., TAOYUAN COUNTY (TW)

(72) Inventors: HSU CHIANG, NEW TAIPEI CITY (TW); YAW-WEN HU, TAOYUAN COUNTY (TW); TZUNG-HAN LEE, TAIPEI CITY (TW); CHUNG-YUAN LEE, TAOYUAN COUNTY (TW); SHENG-HSIUNG WU, TAIPEI CITY (TW)

(73) Assignee: INOTERA MEMORIES, INC., TAOYUAN COUNTY (TW)

(21) Appl. No.: 14/026,135

(22) Filed: Sep. 13, 2013

(30) Foreign Application Priority Data
Mar. 11, 2013 (TW) 102108514

(51) Int. Cl. H01L 49/02

(52) U.S. Cl. CPC H01L 28/40
USPC 257/532; 438/386

(57) ABSTRACT

The present invention provides a stack capacitor structure and a manufacturing method thereof, adapted for a random access memory. The stack capacitor structure is formed on a semiconductor substrate. The stack capacitor structure includes an oxide layer and a circular-shaped stopping layer. The oxide layer is disposed on the semiconductor substrate. The oxide layer has a capacitor trench therein. The circular-shaped stopping layer surrounds an edge of an opening of the capacitor trench. The disclosed stack capacitor structure and the manufacturing method thereof may thereby prevent the occurrence of the stack capacitor structure from having CD variation and belly region causing cell to cell leakage as result of manufacturing process limitation.

### BACKGROUND OF THE INVENTION

1. Field of the Invention

The present invention relates to a capacitor and a manufacturing method thereof; in particular, to a stack capacitor and a manufacturing method thereof.

2. Description of Related Art

In recent years. Dynamic Random Access Memories (DRAMs) have become widely used integrated circuit elements in complying with the miniaturization of various electronic products. With the development in industries, the demand of DRAMs with higher capacity has increased, while the corresponding design is gearing towards high integration and high density. To cope with the development, each memory cell on DRAM elements in practice is arranged very close to other memory cells, which made nearly impossible to expand the capacitor area in horizontal direction, but to increase the capacitor height in vertical direction to increase capacitor area and capacitance.

It is well known that a memory unit of the DRAM generally includes a MOSFET and a capacitor. The capacitor is mainly used for storing charges that represent data, thus the capacitor must have high capacity to ensure that data does not leak easily. One type of capacitors that has been widely used in the modern DRAMs industry is a stack capacitor.

FIG. 1 shows a schematic diagram of a typical stack capacitor structure. As shown in FIG. 1, the formation of a stack capacitor structure 10 in brief is to deposit a first oxide layer 102, a first nitride layer 103, a second oxide layer 104, and a second nitride layer 105 on a substrate 101, sequentially. Then, the opening position of a capacitor trench 107 is defined by a first lithography process. The depth of the capacitor trench 107 is subsequently etched out by a second lithography process. However, when two lithography processes are applied to form the capacitor trench, creating uneven surface profile at the bottom of the capacitor trench, i.e., the shapes and the sizes of the opening and the bottom of the capacitor trench 107 are different, creating a critical dimension variation as the result. Currently in order to etch a deeper capacitor trench 107, a second nitride layer 105 is added additionally to form a longer etching channel 106, so as to have the reactive ions generated by an etching process e.g., a plasma etching process, may etch down vertically to the first oxide layer 102 along the etching channel 106. However, such a method may cause in instability in the etching rate as there are the first and the second nitride layers 103, 105 and the first and the second oxide layers 102, 104 in the capacitor trench. To describe in more detail, the gap between the waist of the adjacent capacitor trenches will become smaller when the waists of the capacitor trench have been over-etched, resulting in leakage between adjacent capacitor trenches forming a short circuit, thereby decrease the production yield.

### SUMMARY OF THE INVENTION

The object of the present invention is to provide a stack capacitor structure and a manufacturing method thereof. An etching trough is formed at first by removing the nitride layer added with relative strong reactive ion etching process to define the position of a capacitor trench. A stopping layer is then deposited on an inner wall of the etching trough to form an etching channel for the capacitor trench. The capacitor trench with depth and width desired is formed subsequently by another etching process. Consequently, the issue of having the waist of the capacitor trench being over-etched causing leakage between the adjacent capacitor trenches to form short circuits can be effectively avoid, thereby increase the production yield.

An embodiment of the present invention provides a stack capacitor structure suitable for DRAMs. The stack capacitor structure is formed on a semiconductor substrate. The stack capacitor structure includes an oxide layer and a circular-shaped stopping layer. The oxide layer is on the semiconductor substrate. The oxide layer has a capacitor trench disposed therein. The circular-shaped stopping layer is formed on the edge of an opening of the capacitor trench. The circular-shaped stopping layer may comprise of an insulation material.

An embodiment of the present invention further provides a manufacturing method of a stack capacitor structure. The manufacturing method comprises the following steps. At first, an oxide layer is formed on a semiconductor substrate. Next, a hard mask layer is formed on the oxide layer. Then, a first etching process is performed to form an etching trough on the oxide layer and the hard mask layer. The opening width of the etching trough is larger than the bottom width of the etching trough. Next, an etching stopping layer is formed on the hard mask layer and the inner wall of the etching trough. Then, a second etching process is performed on the oxide layer through the etching trough so as to form a capacitor trench underneath the etching trough.

Summing up the above, the present invention provides a stack capacitor structure and a manufacturing method thereof, wherein, by means of removing the currently added nitride layer and using a stronger ion bombardment method in a dry etching process of high oxide concentration, an etching trough is etched out on an oxide layer and a nitride layer to define the position of a capacitor trench. A stopping layer is then deposited on the inner wall of the opening of the etching trough to form an etching channel of substantially rectangular shape. Such that the ion bombardment can etch vertically into the oxide layer in another subsequent dry etching process to form the capacitor trench with required width and depth underneath the etching trough. Accordingly, the present invention provides a stack capacitor structure and a manufacturing method thereof which may effectively avoid the occurrence of leakage between the adjacent capacitor trenches as the waist of capacitor trenches forming short circuits due to over-etching, thereby improve the production yield.

In order to further the understanding regarding the present invention, the following embodiments are provided along with illustrations to facilitate the disclosure of the present invention. However, the description and drawings are merely provided for reference and illustration, without any intention to be used for limiting the present invention.

### BRIEF DESCRIPTION OF THE DRAWINGS

FIG. 1 shows a schematic diagram of a typical stack capacitor structure;

FIG. 2 shows a schematic diagram of a stack capacitor structure according to a first embodiment of the present invention;

FIG. 3 shows a flow chart of a manufacturing method for a stack capacitor structure according to a second embodiment of the present invention;

FIG. 4A to FIG. 4H respectively show a schematic diagram illustrating a manufacturing method for a stack capacitor structure according to the second embodiment of the present invention.

### DETAILED DESCRIPTION OF THE PREFERRED EMBODIMENTS

The aforementioned illustrations and following detailed descriptions are exemplary for the purpose of further explaining the scope of the present invention. Other objects and advantages related to the present invention will be illustrated in the subsequent descriptions and appended drawings.

### First Embodiment

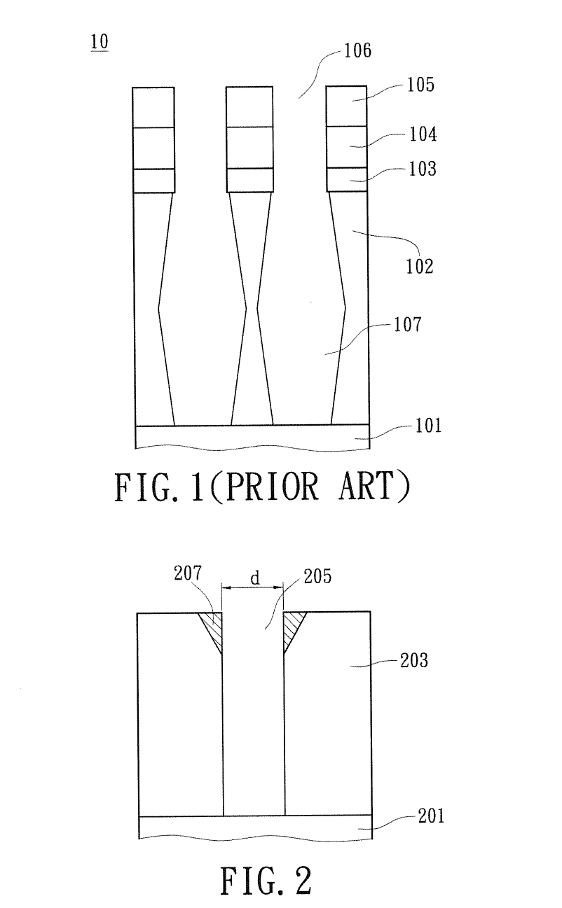

Please refer to FIG. 2. FIG. 2 shows a schematic diagram of a stack capacitor structure according to an embodiment of the present invention. In the present embodiment, the stack capacitor structure may be formed on a semiconductor substrate 201. The stack capacitor structure includes an oxide layer 203 and a circular-shaped stopping layer 207.

In the present embodiment, the semiconductor substrate 201 may include a wafer having film layers, metal wires and semiconductor elements formed thereon. The semiconductor elements may include but not limited to memory elements (e.g., DRAMs, SRAMs, or non-volatile memories), logical elements, and metal-oxide-semiconductor (MOS) transistor elements. However, for simplicity, the semiconductor elements described herein are not shown in FIG. 1. The metal wires may comprise of conductive materials such as doped poly-silicon, metals, and etc., so as to connect the capacitor structure formed subsequently with the elements on the semiconductor substrate 201.

The oxide layer 203 is disposed on the semiconductor substrate 201. The oxide layer 203 may be grown on an upper surface of the semiconductor substrate 201 by means of chemical vapor deposition (CVD) or thermal oxidation. The thickness (e.g., 30 nm) of the oxide layer 203 may be configured according to the required depth of the capacitor trench. The material of the oxide layer 203 may comprise of oxide.

The oxide layer 203 has a capacitor trench 205 disposed therein, wherein the capacitor trench 205 take form of a substantially pillar-shaped, and the horizontal cross section area thereof may be configured to be an ellipsoidal-shaped, a rectangular, or a circular-shaped according to actual process requirement. The shape of the opening and the shape of the bottom of the capacitor trench 205 are substantially identical. The width of the opening of the capacitor trench 205 is substantially the same as the width of the bottom of the capacitor trench 205. The capacitor trench 205 may be formed in the oxide layer 203 by a dry etching process, e.g., a Reactive Ion Etching (RIE) process. Moreover, the size and the shape of the opening of the capacitor trench 205 can be set and defined by a plasma etching process with high oxide concentration and strong bombardment so as to increase the depth of the capacitor trench 205. Accordingly, the bottom of the capacitor trench having uneven profile causing by exposure, and the critical dimension variation and leakage between the capacitor trenches as result of over etching from instability in the etching rate can be effectively overcome.

The capacitor trench 205 may have a predefined width d, and the capacitor trench 205 has a capacitor structure (not shown) disposed therein functioning as a storage capacitor of a DRAM unit. The capacitor structure may be formed by sequentially depositing a first conductive layer, a dielectric layer, and a second conductive layer in the capacitor trench 205 while following the inner surface profile of the capacitor trench 205.

Incidentally, the first conductive layer may be formed by depositing a poly-silicon, a doped poly-silicon, or a titanium oxide. The dielectric layer between the first conductive layer and the second conductive layer may be formed by depositing a dielectric material with high dielectric constant (such as, silicon oxide, silicon nitride, aluminum oxide, or titanium oxide) on the first conductive layer. The second conductive layer may be formed by depositing a conductive material (for example, poly-silicon, doped poly-silicon, titanium oxide, or aluminum oxide) on the dielectric layer. However, the present embodiment is not limited thereto.

In addition, actual structure of the capacitor structure is not the focus of the present invention, and the actual manufacturing method of the capacitor structure is described in the following embodiment and hence further description are hereby omitted.

As shown in FIG. 1, a circular-shaped stopping layer 207 surrounds the edge of the opening of the capacitor trench 205. The circular-shaped stopping layer 207 is formed on the inner surface of the opening of the capacitor trench 205 to have the upper end of the capacitor trench 205 forming a substantially reverse ladder shape so as to facilitate the post process of depositing a conductive material and a dielectric material in the capacitor trench 205 forming the capacitor structure therein. The material of the circular-shaped stopping layer 207 may comprise of an insulation material having high etching selectivity such as Al₂O₃ or nitride. The circular-shaped stopping layer 207 may have an etching rate slower than that of the oxide layer 203 during the dry etching process of using ion gas etching technique, e.g., the plasma etching process. Therefore, a capacitor trench 205 with required depth can be etched out in the oxide layer 203. In addition, the circular-shaped stopping layer 207 may be used to isolate the capacitor trench 205 and other adjacent semiconductor elements disposed above the capacitor trench 205, thereby the stack capacitor structure and other semiconductor elements disposed thereupon are insulated from each other.

It is necessary to be mentioned that FIG. 2 is only used to explain the structure of the stack capacitor structure provided by the instant embodiment, and the present invention is not limited thereto.

### Second Embodiment

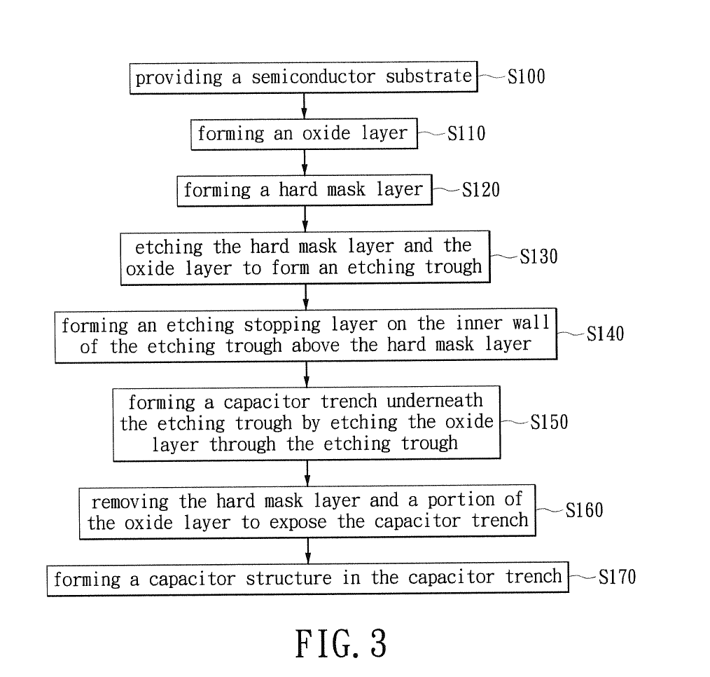

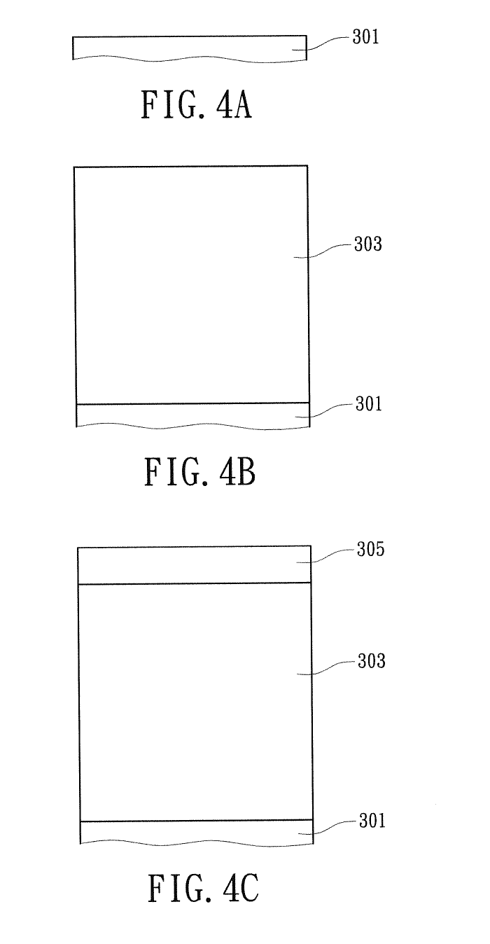

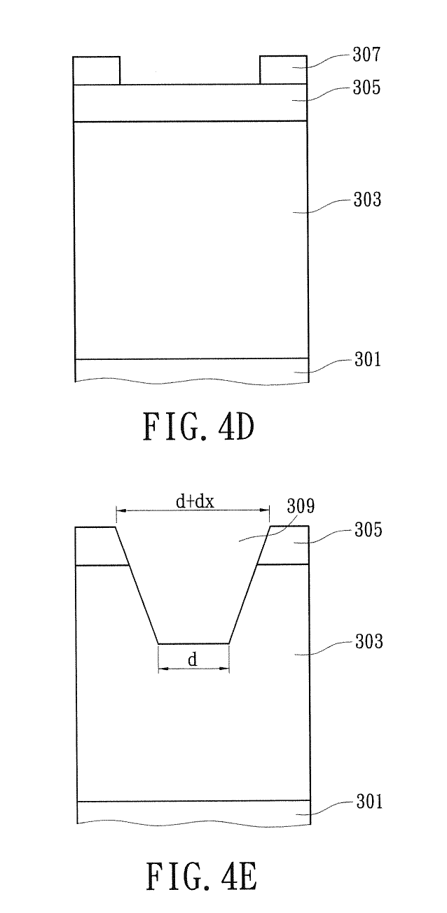

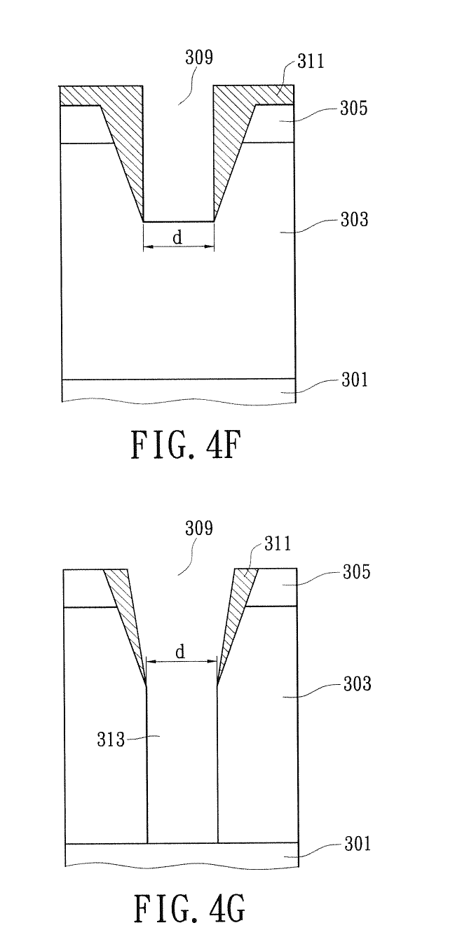

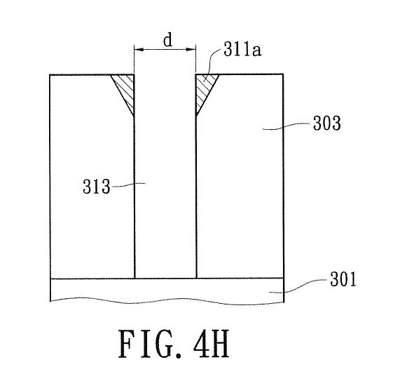

Next, a manufacturing method of a stack capacitor structure is provided additionally by the present invention. Please refer to FIG. 3 in conjunction with FIG. 4A to FIG. 4H. FIG. 3 shows a flow chart of a manufacturing method for a stack capacitor structure according to second embodiment of the present invention. FIG. 4A to FIG. 4H respectively show a schematic diagram illustrating a manufacturing method for a stack capacitor structure according to second embodiment of the present invention.

In step S100, as shown in FIG. 4A, a semiconductor substrate 301 is provided. The semiconductor substrate 301 may include a wafer having thin film layers, metal wires and semiconductor elements formed on thereon. The semiconductor elements include but not limited to memory elements (e.g., DRAMs, SRAMs, or non-volatile memories), logical elements, metal-oxide-semiconductor (MOS) transistor elements, and etc. However, for simplicity, the semiconductor elements described herein are not shown in FIG. 4A to FIG. 4H.

Next, in step S110, as shown in FIG. 4B, an oxide layer 303 is formed on the upper surface of the semiconductor substrate 301. The material of the oxide layer 303 may comprise of silicon oxide, and may be deposited on the semiconductor substrate 301 by means of chemical vapor deposition or thermal oxidation. The thickness (for example, 30 nm) of the oxide layer 303 may be configured according to the required depth of the capacitor trench (not shown in FIG. 4B). Those skilled in the art should understand that the depth of the capacitor trench is related to the required capacitance, thus the thickness of the oxide layer 303 may be configured according to the actual required capacitance.

Next, in step S120, as shown in FIG. 4C, a hard mask layer 305 is formed on the oxide layer 303. The material of the hard mask layer 305 may be comprised of silicon nitride, silicon oxy-nitride, silicon carbide, or silicon carbon-nitride, and can be deposited on the oxide layer 303 with chemical vapor deposition.

Next, in step S130, a first etching process is performed to etch the oxide layer 303 and the hard mask layer 305 so as to form an etching trough on the oxide layer 303 and the hard mask layer 305. The bottom of the etching trough corresponds to the position of the capacitor trench. The etching trough may be used as an etching channel for forming the capacitor trench with required depth so as to effectively etch out the depth required for the capacitor trench. At the same time, the etching trough may also be used to prevent the formation of a belly-shaped region around on the waist area of the capacitor trench due to instability in the etching rate.

To put it concretely, as shown in FIG. 4D, a patterned photoresist layer 307 is formed on the hard mask layer 305 to define the position of the capacitor trench. The patterned photoresist layer 307 may be, for example, a positive photoresist which can be coated on the hard mask layer 305 by means of a coating method. The patterns corresponding to the position and the shape of the capacitor trench are disposed on the patterned photoresist layer 307 through exposure and develop processes. The position pattern associated with the capacitor trench may be designed according to the position of the semiconductor element (for example, MOSFET) disposed on the semiconductor substrate 301, while the shape pattern of the capacitor trench may be circle, square, ellipsoid, or other geometric patterns and the present embodiment is not limited thereto.

Next, as shown in FIG. 4E, a first etching process is performed using the patterned photoresist layer 307 as a mask, and the exposed areas on the patterned photoresist layer 307 are removed. That is etching the hard mask layer 305 and oxide layer 303 underneath the patterned photoresist layer 307to form an etching trough 309 such that the position and width of the capacitor trench can be defined. The depth of the etching trough 309 is larger than the thickness of the hard mask layer 305. The etching trough 309 extends from the surface of the hard mask layer 305 downwards to a portion of the oxide layer 303.

The etching trough 309 may be etched by using dry etching method (for example, the reactive ion etching method), and is etched using a plasma etching with strong bombardment and high oxide concentration. Since the etching trough 309 is not formed by the existing method of stacking the hard mask layer 305 and the oxide layer 303 alternatively, so that the etching trough 309 as shown in FIG. 4E can form an etching channel of substantially reverse ladder-shaped using a plasma etching method with strong bombardment and high oxide concentration. In other words, the opening width of the etching trough 309 is larger than bottom width of the etching trough 309. As shown in FIG. 4E, the bottom width of the etching trough 309 is denoted as d, and the opening width of the etching trough 309 is d+dx. The unexposed patterned photoresist layer 307 is further removed by using a dry etching or a wet etching photoresist-removal method.

Next, in step S140, as shown in FIG. 4F, an etching stopping layer 311 is formed on the hard mask layer 305 and the inner wall surface of the etching trough 309. The etching stopping layer 311 covers the inner wall surface of the etching trough 309. The thickness that the etching stopping layer 311 covering the inner wall surface of the etching trough 309 can be defined according to the width of the capacitor trench required. The etching stopping layer 311 causes the etching trough 309 to form a rectangular-shaped etching channel functioning as an upright etching channel for etching the capacitor trench. The etching stopping layer 311 can be used as a protection layer of both the oxide layer 303 and the hard mask layer 305 in a subsequent etching process of the capacitor trench to prevent the reactive ions injected from etching the side walls of the oxide layer 303 and the hard mask layer 305. At the same time, the trench width of the capacitor trench can be fixed by the etching trough 309, so as to facilitate the subsequent etching process of the etching trough.

The material of the etching stopping layer 311 is a material with high selectivity, such as an insulation material, e.g., Al₂O₃, nitride, or etc. The high selectivity in the instant embodiment means that the etching rate of the etching stopping layer 311 is slower than the etching rate of the oxide layer 303 (to-be-etched material) in the etching process. Henceforth, the reactive ions injected during the etching process are prevented from etching toward the side walls of the oxide layer 303 and the hard mask layer 305. The reactive ions are further directed to etch the oxide layer 303 under the etching trough 309 through the etching trough 309. The etching stopping layer 311 may be formed on the hard mask layer 305 and the inner wall surface of the etching trough 309 using either chemical vapor deposition or atomic layer deposition.

Next, in step S150, as shown in FIG. 4G, a second etching process is performed to the oxide layer 303 through the etching trough 309, so as to form a capacitor trench 313 underneath the etching trough 309. The second etching process can be realized by a dry etching method, for example, the oxide layer 303 may be etched using the reactive ion etching method. Specifically, a plasma etching process (i.e., reactive ions are injected) may be applied to etch the oxide layer 303 anisotropically through the etching trough 309 downwards to the upper surface of the semiconductor substrate 301to form the capacitor trench 313. As shown in FIG. 4G, the upper end of the capacitor trench 313 takes form of a reverse ladder shape as a portion of the etching stopping layer 311 remained around the edge of the opening of the capacitor trench 313.

The depth of the capacitor trench 313 is substantially larger than or equal to the thickness of the oxide layer 303. The capacitor trench 313 has a predefined width d which is defined by the bottom width of the etching trough 309 described in the previous steps.

It is worth mentioning that, during the second etching process, the etching rate of the oxide layer 303 is higher than the etching rate of the etching stopping layer 311. The etching stopping layer 311 thus can prevent the oxide layer 303 and the hard mask layer 305 covered by the etching trough 309 from being etched during the second etching process. Thereby, the injected reactive ions can directly cut into the oxide layer 303 underneath the etching trough 309.

That is to say, the etching stopping layer 311 is disposed to have the etching trough 309 forming a rectangular-shaped channel during the second etching process. Such that the injected reactive ions can be direct vertically downward and to anisotropically etch the oxide layer 303 underneath the etching trough 309 and the etching rate is stabilized, and furthermore the shape of the opening of the capacitor trench 313 is substantially identical to the shape of the bottom thereof. The horizontal cross section of the capacitor trench 313 may take form of a geometric shape such as an ellipsoid shape, a rectangular shape, or a circular shape. The opening width of the capacitor trench 313 is substantially equal to the bottom width of the capacitor trench 313.

Thereby the present invention can overcome the phenomenon of critical dimension as result of the profile unevenness at the bottom of the capacitor trench due to twice exposure in the lithography. At the same time, the trench structure of the capacitor trench may be configured to take form of a pillar shape. So that the issues of ions injected having different etching rate with respect to stack layers of different materials during the etching process can be resolved. Consequently, the problem of incomplete etching of the bottom of the capacitor trench due to instability in the etching rate causing the capacitor trench to have belly shape around the waist area thereof forming short circuit between adjacent capacitor trenches can be effective eliminated.

In step S160, as shown in FIG. 4H, the hard mask layer 305 and a partial oxide layer 303 are removed in a third etching process to expose the capacitor trench 313. The method of removing the hard mask layer 305 and a portion of the oxide layer 303 may be carried out by photoresist deposition and selective etching technique, such that the opening of the capacitor trench 313 is flush with the upper surface of the oxide layer 303. In addition, the third etching performed in the present embodiment will not completely remove the etching stopping layer 311, i.e., a portion of the etching stopping layer 311 still remains on the inner wall of the opening of the capacitor trench 313 forming a circular-shaped stopping layer 311a.

As shown in FIG. 4H, the circular-shaped stopping layer 311a is formed on the edge the opening of the capacitor trench 313, such that the opening of the capacitor trench 313 having shape of reverse shape, which is advantageous to the subsequent depositing or filling process of forming the capacitor structure. Additionally, the circular-shaped stopping layer 311a can be used for isolating the capacitor trench 313 and adjacent semiconductor elements disposed on the capacitor trench 313, such that the stack capacitor structure can be isolated from other semiconductor elements.

In step S170, a capacitor structure is formed in the capacitor trench 313. For example, a first conductive layer (not shown) along the inner wall profile of the capacitor trench 313 using the epitaxial growth technique or the chemical vapor deposition. A dielectric layer (not shown) is then deposited with chemical vapor deposition, and the dielectric layer is formed along the inner wall profile of the capacitor trench 313 so as to cover the first conductive layer. Next, a conductive material is deposited on the dielectric layer using chemical vapor deposition or atomic layer deposition to form a second conductive layer (not shown)

The materials of the first and the second conductive layers may comprise of conductive materials such as poly-silicon, doped poly-silicon, titanium, titanium oxide, or etc. The top views of the first and the second conductive layers may have an ellipsoid shape, a ring shape, a rectangular shape, or other geometric shapes, wherein the shapes may be configured according to the actual architecture of the capacitor trench 313 and the instant embodiment not limited thereto. The material of the dielectric material may comprise of silicon oxide or other dielectric materials with high dielectric coefficient.

The first conductive layer may be a lower electrode of a capacitor structure, while the second conductive layer may be an upper electrode of a capacitor structure. The dielectric layer is placed between the first conductive layer and the second conductive layer. The thickness of the dielectric layer can be arranged by configuring the width of the capacitor trench so as to increase the capacitance of the capacitor structure. In other words, the inner wall area of the capacitor trench can be increased by adjusting the depth of the capacitor trench so as to increase the capacitance thereof.

Accordingly, during the etching process the etching rate would not decrease the production yield of the capacitor trenches while the capacitance of the capacitor trenches can be increased by increasing the depth of the capacitor trench. In other words, a required trench depth can be attained in the present invention to increase the capacitance by utilizing the aforementioned manufacturing processes. FIG. 3 and FIG. 4A˜FIG. 4H are only used for describing a manufacturing method of a capacitor trench and shall not be used to limit the present invention. In practice, one or more capacitor trenches can be manufactured according to requirement at the same time and arranged distributely with space in between on the semiconductor substrate.

Summing up the above, the present invention provides a stack capacitor structure and a manufacturing method thereof, wherein, by means of removing the currently added nitride layer and using a stronger ion bombardment method in a dry etching process of high oxide concentration, an etching trough is etched out on an oxide layer and a nitride layer to define the position of a capacitor trench. A stopping layer is then deposited on the inner wall of the opening of the etching trough to form an etching channel of substantially rectangular shape. Such that the ion bombardment can etch vertically into the oxide layer in another subsequent dry etching process to form the capacitor trench with required width and depth.

Thereby, the embodiment of the present invention provides a stack capacitor structure and a manufacturing method thereof, which may effectively avoid the occurrence of leakage between the adjacent capacitor trenches when the waist of capacitor trenches forms short circuit as result of over-etched and thereby improve the production yield. In addition, the etching technique described may be further performed to increase the depth of the stack capacitor structure to enhance the capacitor area and capacitance.

The descriptions illustrated supra set forth simply the preferred embodiments of the present invention; however, the characteristics of the present invention are by no means restricted thereto. All changes, alterations, or modifications conveniently considered by those skilled in the art are deemed to be encompassed within the scope of the present invention delineated by the following claims.

What is claimed is:

1. A stack capacitor structure, formed on a semiconductor substrate, comprising:
an oxide layer, formed on the semiconductor substrate, the oxide layer having a capacitor trench disposed therein; and
a circular-shaped stopping layer, formed on an edge of an opening of the capacitor trench;
wherein the circular-shaped stopping layer comprises of an insulation material.

2. The stack capacitor structure according to claim 1, wherein the capacitor trench has a substantially pillar-shaped profile.

3. The stack capacitor structure according to claim 1, wherein the circular-shaped stopping layer comprises of Al₂O₃ or silicon nitride.

4. A manufacturing method of a stack capacitor structure, comprising:
forming an oxide layer on a semiconductor substrate;
forming a hard mask layer on the oxide layer;
performing a first etching process to form an etching trough on the oxide layer and the hard mask layer, the opening width of the etching trough being larger than the bottom width of the etching trough;
forming an etching stopping layer on the hard mask layer and an inner wall of the etching trough; and
performing a second etching process on the oxide layer through the etching trough so as to form a capacitor trench underneath the etching trough.

5. The manufacturing method according to claim 4, wherein the first etching process and the second etching process are implemented by a dry etching process.

6. The manufacturing method according to claim 4, wherein the depth of the etching trough is larger than the thickness of the hard mask layer.

7. The manufacturing method according to claim 4, wherein after the step of forming the capacitor trench, the method comprises:
removing the hard mask layer and a portion of the oxide layer to expose a portion of the capacitor trench; and
forming a capacitor structure in the capacitor trench;
wherein the capacitor structure comprises of a first conductive layer, a dielectric layer, and a second conductive layer.

8. The manufacturing method according to claim 7, wherein the step of removing the hard mask layer, and a portion of the oxide layer comprises:
reserving a portion of the etching stopping layer so as to form a circular-shaped stopping layer on an edge of an opening of the capacitor trench.

9. The manufacturing method according to claim 5, wherein the etching stopping layer comprises of Al₂O₃ or silicon nitride.

10. The manufacturing method according to claim 5, wherein the etching stopping layer is formed on the hard mask layer and the inner wall of the etching trough by means of a chemical vapor deposition.
